(19) United States
(12) Patent Application Publication
(10) Pub. No.: US 2024/0056052 A1
(43) Pub. Date: Feb. 15, 2024

(54) ACOUSTIC WAVE DEVICE, FILTER AND MULTIPLEXER

(71) Applicant: TAIYO YUDEN CO., LTD., Tokyo (JP)

(72) Inventor: Mamoru ISHIDA, Tokyo (JP)

(73) Assignee: TAIYO YUDEN CO., LTD., Tokyo (JP)

(21) Appl. No.: 18/446,371

(22) Filed: Aug. 8, 2023

(30) Foreign Application Priority Data
Aug. 10, 2022 (JP) 2022-128123

(51) Int. Cl. H03H 9/17; H03H 9/56

(52) U.S. Cl. CPC H03H 9/172; H03H 9/568

(57) ABSTRACT

An acoustic wave device includes a substrate, a lower electrode provided on the substrate, a piezoelectric layer provided on the lower electrode, an upper electrode provided on the piezoelectric layer to form a resonance region facing the lower electrode, and a multilayered acoustic reflection film provided between the substrate and the lower electrode in the resonance region, the acoustic reflection film having low acoustic impedance films and high acoustic impedance films alternately laminated, and the acoustic reflection film satisfying 0<(G3−G2)/G1<0.96 where G1 is a product of an average thickness in the resonance region and a density of a first film, G2 is a product of an average thickness and a density of the lower electrode in the resonance region, and the G3 is a product of an average thickness in the resonance region and a density of a second film.

### FIELD

A certain aspect of the present disclosure relates to an acoustic wave device, a filter, and a multiplexer.

### BACKGROUND

A filter and a duplexer using a piezoelectric thin film resonator are known as a filter and a duplexer for a high-frequency circuit of a radio terminal such as a portable telephone. The piezoelectric thin film resonator includes an FBAR (Film Bulk Acoustic Resonator) type and an SMR (Solid Mounted Resonator) type. The FBAR-type piezoelectric thin film resonator is provided with a piezoelectric layer on a substrate and a lower electrode and an upper electrode sandwiching the piezoelectric layer, wherein a cavity is formed under the lower electrode in a region where the lower electrode and the upper electrode face each other and sandwich the piezoelectric layer. The SMR-type piezoelectric thin film resonator is provided with an acoustic reflection film in which films having a low acoustic impedance and films having a high acoustic impedance are alternately laminated, instead of the cavity. The region where the lower electrode and the upper electrode face each other and sandwich the piezoelectric layer is a resonance region where the acoustic wave resonates. It is known that a single-crystal lithium niobate layer or a single-crystal lithium tantalate layer having a large electromechanical coupling coefficient is used for the piezoelectric layer (for example, Patent Document 1).

### PRIOR ART DOCUMENTS

### [Patent Document]

[Patent Document 1] Japanese Patent Application Publication No. 2008-42871

### SUMMARY OF THE INVENTION

In the piezoelectric thin film resonator, spurious caused by a second harmonic may occur. For example, when the single-crystal lithium niobate layer or the single-crystal lithium tantalate layer is used for the piezoelectric layer to obtain the large electromechanical coupling coefficient, the spurious caused by the second harmonic of the thickness-shear vibration is likely to increase.

In view of the circumstances as described above, an object of the present disclosure is to suppress the spurious caused by the second harmonic.

(1) According to a first aspect of the embodiments, there is provided an acoustic wave device including: a substrate; a lower electrode provided on the substrate; a piezoelectric layer provided on the lower electrode; an upper electrode provided on the piezoelectric layer so as to form a resonance region facing the lower electrode, the upper electrode and the lower electrode sandwiching the piezoelectric layer; and a multilayered acoustic reflection film provided between the substrate and the lower electrode in the resonance region, the acoustic reflection film having one or more low acoustic impedance films and one or more high acoustic impedance films which are alternately laminated, and the acoustic reflection film satisfying 0<(G3−G2)/G1<0.96 where the G1 is a product of an average thickness in the resonance region of a first film and a density of the first film, the first film being a film closest to the lower electrode out of the one or more low acoustic impedance films and the one or more high acoustic impedance films, the G2 is a product of an average thickness of the lower electrode in the resonance region and a density of the lower electrode, and the G3 is a product of an average thickness in the resonance region of a second film including the upper electrode provided on the piezoelectric layer in the resonance region and a density of the second film.

(2) According to a second aspect of the embodiments, there is provided an acoustic wave device including: a substrate; a lower electrode provided on the substrate; a piezoelectric layer provided on the lower electrode; an upper electrode provided on the piezoelectric layer so as to form a resonance region facing the lower electrode, the upper electrode and the lower electrode sandwiching the piezoelectric layer; and a multilayered acoustic reflection film provided between the substrate and the lower electrode in the resonance region, the acoustic reflection film having one or more first films and one or more second films which are alternately laminated, the one or more first films including at least one of a silicon oxide film, a magnesium film, an aluminum film, and a titanium film, the one or more second films including at least one of a silicon nitride film, an aluminum nitride film, a copper film, an aluminum oxide film, a gold film, a molybdenum film, a tungsten film, and a tantalum oxide film, and the acoustic reflection film satisfying 0<(G3−G2)/G1<0.96 where the G1 is a product of an average thickness in the resonance region of a third film and a density of the third film, the third film being a film closest to the lower electrode out of the one or more first films and the one or more second films, the G2 is a product of an average thickness of the lower electrode in the resonance region and a density of the lower electrode, and the G3 is a product of an average thickness in the resonance region of a fourth film including the upper electrode provided on the piezoelectric layer in the resonance region and a density of the fourth film.

(3) In the above configurations (1) and (2), 0.1<(G3−G2)/G1<0.75 may be satisfied.

(4) In the above configurations (1) and (2), 0.3<(G3−G2)/G1<0.55 may be satisfied.

(5) In the above configurations (1) and (2), the upper electrode may be thicker than the lower electrode in the resonance region.

(6) In the above configuration (1), the one or more low acoustic impedance films may be silicon oxide films.

(7) In the above configuration (6), the first film may be a low acoustic impedance film.

(8) In the above configuration (1), the second film may include the upper electrode and an insulating film provided on the upper electrode. In the above configuration (2), the fourth film may include the upper electrode and an insulating film provided on the upper electrode.

(9) In the above configurations (1) and (2), the piezoelectric layer may be a single-crystal lithium niobate layer or a single-crystal lithium tantalate layer.

(10) According to a third aspect of the embodiments, there is provided an acoustic wave device including: a substrate; a lower electrode provided on the substrate; a piezoelectric layer provided on the lower electrode and being a single-crystal lithium niobate layer or a single-crystal lithium tantalate layer; an upper electrode provided on the piezoelectric layer so as to form a resonance region facing the lower electrode, the upper electrode and the lower electrode sandwiching the piezoelectric layer above a cavity provided below the lower electrode; and an insulating film provided between the cavity and the lower electrode in the resonance region and satisfying 0<(G3−G2)/G1<1.6, where the G1 is a product of an average thickness of the insulating film in the resonance region and a density of the insulating film in the resonance region, the G2 is a product of an average thickness of the lower electrode in the resonance region and a density of the lower electrode, and the G3 is a product of an average thickness of a first film including the upper electrode provided on the piezoelectric layer in the resonance region and a density of the first film.

(11) According to a fourth aspect of the embodiments, there is provided a filter including the acoustic wave device according to the above configurations (1), (2) and (10).

(12) According to a fifth aspect of the embodiments, there is provided a multiplexer including the filter according to the above configuration (11).

### BRIEF DESCRIPTION OF THE DRAWINGS

FIG. 1A is a plan view of an acoustic wave device according to a first embodiment;

FIG. 1B is a cross-sectional view taken along line A-A of FIG. 1A;

FIGS. 2A and 2B are diagrams illustrating the crystal orientation of a piezoelectric layer when the piezoelectric layer is a lithium niobate layer or a lithium tantalate layer;

FIG. 3A is a diagram illustrating an absolute value Y of admittance with respect to a frequency of the first embodiment and a first comparative example in simulation;

FIG. 3B is an enlarged view of a region A in FIG. 3A;

FIG. 4A is a diagram illustrating displacement of the second harmonic vibration of the thickness-shear vibration of the first comparative example in the simulation;

FIG. 4B is a diagram illustrating displacement of the second harmonic vibration of the thickness-shear vibration of the first embodiment in the simulation;

FIG. 5A is a diagram illustrating a simulation result of the magnitude of the spurious caused by the second harmonic of the thickness-shear vibration with respect to the thickness of the upper electrode;

FIG. 5B is a diagram illustrating a case where the horizontal axis in FIG. 5A is converted into α in an equation (1);

FIG. 6 is a cross-sectional view of the acoustic wave device according to a first modification of the first embodiment;

FIG. 7A is a diagram illustrating an absolute value Y of admittance with respect to a frequency of the first modification of the first embodiment and a second comparative example in the simulation;

FIG. 7B is an enlarged view of a region A in FIG. 7A;

FIG. 8 is a cross-sectional view of an acoustic wave device according to a second modification of the first embodiment;

FIG. 9A is a diagram illustrating an absolute value Y of admittance to a frequency of the second modification of the first embodiment and the first comparative example in the simulation;

FIG. 9B is an enlarged view of a region A in FIG. 9A;

FIG. 10 is a diagram illustrating an absolute value Y of admittance to a frequency of a third comparative example and a fourth comparative example in the simulation;

FIGS. 11A to 11D are plan views illustrating another examples of the upper electrode;

FIG. 12 is a cross-sectional view of an acoustic wave device according to a second embodiment;

FIG. 13A is a diagram illustrating a simulation result of a magnitude of the spurious corresponding to a thickness T of the upper electrode;

FIG. 13B is a diagram illustrating a case where the horizontal axis in FIG. 13A is converted into α in an equation (3);

FIG. 14 is a circuit diagram of a filter according to a third embodiment; and

FIG. 15 is a circuit diagram of a duplexer according to a fourth embodiment.

### DETAILED DESCRIPTION

Embodiments of the present disclosure will be described below with reference to the drawings.

### First Embodiment

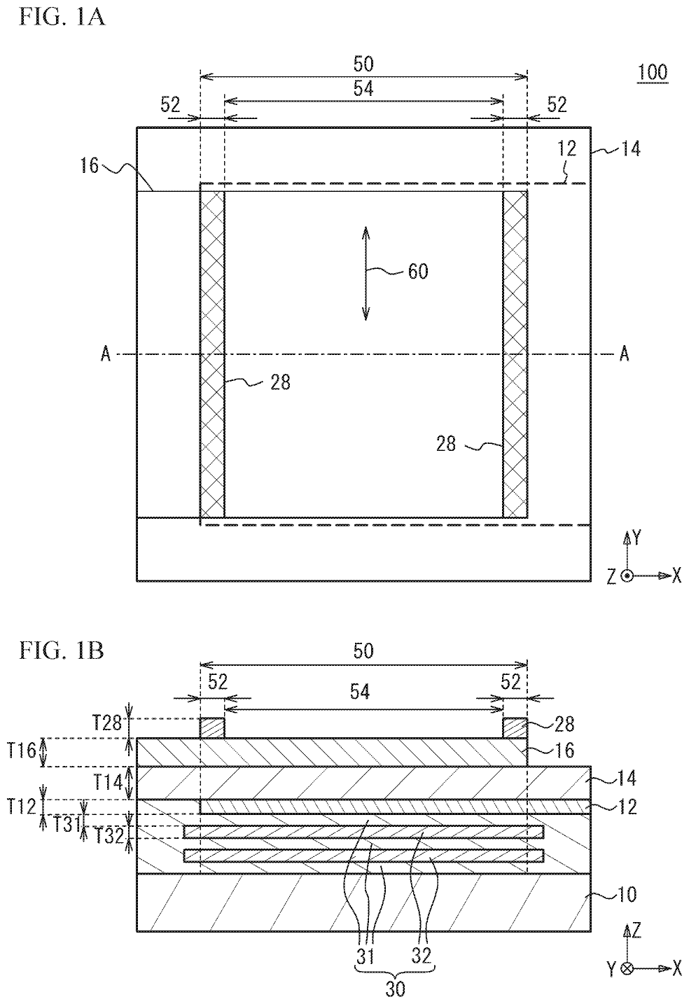

FIG. 1A is a plan view of an acoustic wave device 100 according to a first embodiment, and FIG. 1B is a cross-sectional view taken along line A-A of FIG. 1A. In FIG. 1A, an additional film 28 is hatched for clarity of the drawing. A thickness direction of a piezoelectric layer 14 is defined as a Z direction, a direction in which a lower electrode 12 is drawn out from a resonance region 50 out of the planar directions of the piezoelectric layer 14 is defined as a +X direction, a direction in which an upper electrode 16 is drawn out from the resonance region 50 is defined as a −X direction, and a direction orthogonal to the X direction is defined as a Y direction. The X direction, the Y direction, and the Z direction do not necessarily correspond to an X axis direction, a Y axis direction, and a Z axis direction of the crystal orientation of the piezoelectric layer 14.

As illustrated in FIGS. 1A and 1B, the acoustic wave device 100 is a piezoelectric thin film resonator, an acoustic reflection film 30 is provided on a substrate 10, and the piezoelectric layer 14 is provided on the acoustic reflection film 30. The upper and lower surfaces of the piezoelectric layer 14 are substantially flat. The upper electrode 16 and the lower electrode 12 are provided on and under the piezoelectric layer 14, respectively. The thickness of the upper electrode 16 is larger than that of the lower electrode 12, for example. A region in which the lower electrode 12 and the upper electrode 16 sandwich at least a part of the piezoelectric layer 14 and overlap each other in planar view is the resonance region 50.

The substrate 10 may be, for example, a silicon substrate, a sapphire substrate, an alumina substrate, a spinel substrate, a quartz substrate, a quartz substrate, a glass substrate, a ceramic substrate, or a GaAs substrate. The piezoelectric layer 14 is, for example, a single-crystal lithium niobate layer, a single-crystal lithium tantalate layer, an aluminum nitride layer, a zinc oxide layer, a lead zirconate titanate layer, or a lead titanate layer. The thickness of the piezoelectric layer 14 is, for example, about 200 nm to 1000 nm. The lower electrode 12 and the upper electrode 16 are a single-layer film or a laminated film of ruthenium (Ru), chromium (Cr), aluminum (Al), titanium (Ti), copper (Cu), molybdenum (Mo), tungsten (W), tantalum (Ta), platinum (Pt), rhodium (Rh), iridium (Ir), or the like. The thicknesses of the lower electrode 12 and the upper electrode 16 are about 20 nm to 150 nm, for example.

When high-frequency power is applied between the lower electrode 12 and the upper electrode 16, an acoustic wave is excited in the piezoelectric layer 14 in the resonance region 50. The wavelength of the acoustic wave is approximately twice the thickness of the piezoelectric layer 14. When the piezoelectric layer 14 is the single-crystal lithium niobate layer or the single-crystal lithium tantalate layer, the acoustic wave in which the displacement of the acoustic wave vibrates in a direction substantially perpendicular to the Z direction (i.e., a strain direction with respect to the thickness) is excited in the piezoelectric layer 14. This vibration is called thickness-shear vibration. A direction in which the displacement of the thickness-shear vibration is largest (the displacement direction of the thickness-shear vibration) is set as a vibration direction 60 of the thickness-shear vibration. Here, the vibration direction 60 of the thickness-shear vibration is the Y direction. The lower electrode 12 and the upper electrode 16 are drawn out from the resonance region 50 in a direction intersecting (e.g., orthogonal to) the vibration direction 60 of the thickness-shear vibration. The planar shape of the resonance region 50 is substantially rectangular. The substantially rectangular shape has four substantially straight sides. One pair of the four sides extends in the Y direction, and another pair of the four sides extends in the X direction. When the piezoelectric layer 14 is an aluminum nitride layer, a zinc oxide layer, a lead zirconate titanate layer, or a lead titanate layer, an acoustic wave of a thickness longitudinal vibration mode is mainly excited in the piezoelectric layer 14.

The resonance region 50 has a central region 54 and edge regions 52 on both sides of the central region 54 in the X direction. The edge region 52 extends substantially in the Y direction. The width of the edge region 52 in the X direction is substantially constant in the Y direction. The additional film 28 is provided on the upper electrode 16 of the edge region 52. The additional film 28 is not provided in the central region 54 of the resonance region 50 sandwiched between the edge regions 52. The additional film 28 is a metal film as exemplified for the lower electrode 12 and the upper electrode 16, or an insulating film such as a silicon oxide film, a silicon nitride film, an aluminum oxide film, a tantalum oxide film, or a niobium oxide film. The material of the additional film 28 may be the same as or different from the materials of the lower electrode 12 and the upper electrode 16. By providing the additional film 28, a piston mode is realized.

In the acoustic reflection film 30, low acoustic impedance films 31 each having a low acoustic impedance and high acoustic impedance films 32 each having a high acoustic impedance are alternately provided. The thicknesses of the low acoustic impedance film 31 and the high acoustic impedance film 32 are approximately λ/4 (λ, is a wavelength of the acoustic wave), for example. Thus, the acoustic reflection film 30 reflects the acoustic wave. The number of layers of the low acoustic impedance film 31 and the high acoustic impedance film 32 can be set freely. The acoustic reflection film 30 may be formed by laminating at least two kinds of layers having different acoustic characteristics with an interval therebetween. Further, the substrate 10 may be one of at least two kinds of layers having different acoustic characteristics of the acoustic reflection film 30. For example, the acoustic reflection film 30 may have a structure in which one layer of films having different acoustic impedances is provided in the substrate 10. In planar view, the acoustic reflection film 30 overlaps with the resonance region 50, and the acoustic reflection film 30 is the same size as the resonance region 50 or larger than the resonance region 50.

The low acoustic impedance film 31 is a dielectric film such as a silicon oxide (SiO₂) film, for example, but may be a metal film such as a magnesium (Mg) film, an aluminum (Al) film, or a titanium (Ti) film. The metal film is used for the plurality of low acoustic impedance films 31, except for a film in contact with the lower electrode 12, and the dielectric film is used for the film in contact with the lower electrode 12. Thus, the low acoustic impedance film 31 can be a film including at least one of the silicon oxide film, the magnesium film, the aluminum film, and the titanium film. The high acoustic impedance film 32 is, for example, a metal film such as a tungsten (W) film, a copper (Cu) film, a gold (Au) film, or a molybdenum (Mo) film, or a dielectric film such as a silicon nitride (SiN) film, an aluminum nitride (AlN) film, an aluminum oxide (Al₂O₃) film, or a tantalum oxide (Ta₂O₅) film. Thus, the high acoustic impedance film 32 can be a film including at least one of the silicon nitride film, the aluminum nitride film, the copper film, the aluminum oxide film, the gold film, the molybdenum film, the tungsten film, and the tantalum oxide film. In the acoustic reflection film 30, for example, a film closest to the lower electrode 12 is the low acoustic impedance film 31.

The thickness of the additional film 28 is represented by T28. The thickness of the upper electrode 16 is represented by T16. The thickness of the piezoelectric layer 14 is represented by T14. The thickness of the lower electrode 12 is represented by T12. The thickness of the low acoustic impedance film 31 at a portion overlapping the resonance region 50 in planar view is represented by T31. The thickness of the high acoustic impedance film 32 at a portion overlapping the resonance region 50 in planar view is represented by T32. The thickness T16 of the upper electrode 16 is larger than the thickness T12 of the lower electrode 12.

[Crystal Orientation]

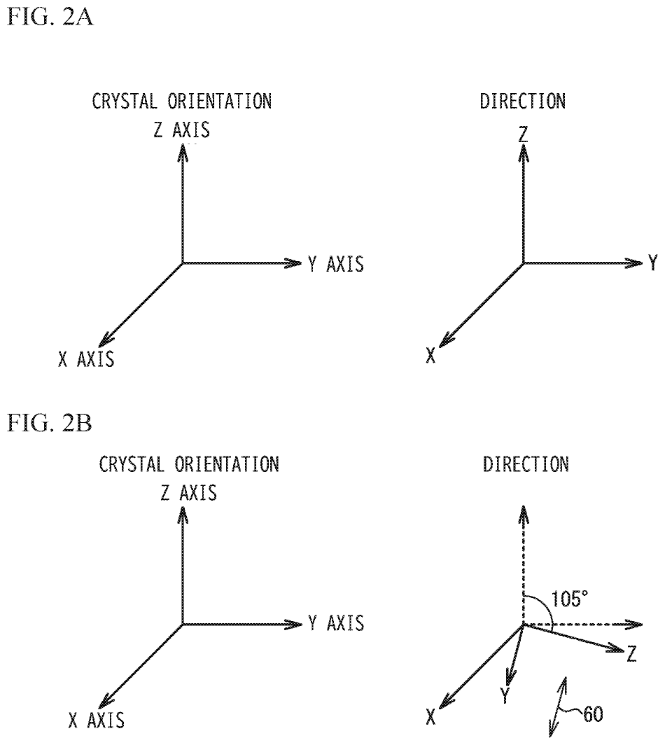

FIGS. 2A and 2B are diagrams illustrating the crystal orientation of the piezoelectric layer 14 when the piezoelectric layer 14 is the lithium niobate layer or the lithium tantalate layer. In FIGS. 2A and 2B, arrows on the left side indicate directions of crystal axes of the piezoelectric layer 14. The right solid line arrows correspond to the X direction, the Y direction, and the Z direction in FIGS. 1A and 1B. First, the definition of the Euler's angle (φ, θ, ψ) will be described. In a right-handed XYZ coordinate system, a direction normal to the upper surface of the piezoelectric layer 14 is defined as a Z direction, and directions orthogonal to the Z direction and orthogonal to each other in the surface direction of the upper surface of the piezoelectric layer 14 are defined as an X direction and a Y direction. First, the X direction, the Y direction, and the Z direction are respectively defined as the X axis direction, the Y axis direction, and the Z axis direction of the crystal orientation. Next, the XYZ coordinate system is rotated by an angle φ from the +X direction to the +Y direction around the Z direction. The XYZ coordinate system is rotated by an angle θ from the +Y direction to the +Z direction around the X direction after the rotation of the angle φ. The XYZ coordinate system is rotated by an angle w from the +Z direction to the +X direction around the Y direction after the rotation of the angle θ. The Euler's angle for such rotation is (φ, θ, ψ). The Euler's angle expressed using (φ, θ, ψ) includes equivalent Euler's angle.

As illustrated in FIG. 2A, the +X direction, the +Y direction, and the +Z direction are defined as the +X axis direction, the +Y axis direction, and the +Z axis direction of the crystal orientation, respectively. As illustrated in FIG. 2B, from the state of FIG. 2A, the +Y direction and the +Z direction are rotated by 105° from the +Y direction to the −Z direction on the YZ plane around the X direction. When the XYZ coordinate system is rotated in this manner, a direction in which the +Z axis direction of the crystal orientation is rotated by 105° toward the +Y axis direction is the +Z direction. At this time, the Y direction becomes the vibration direction 60 of the thickness-shear vibration. The Euler's angle is (0°, −105°, 0°).

The normal direction (Z direction) of the upper surface of the piezoelectric layer 14 is a direction in the plane composed of the Y-axis and the Z-axis. Thereby, the thickness-shear vibration occurs in the planar direction of the piezoelectric layer 14. The X-axis direction is preferably within a range of ±5° and more preferably within a range of ±1° from the planar direction of the piezoelectric layer 14. The normal direction (Z direction) of the upper surface of the piezoelectric layer 14 is a direction in which the +Z axis direction of the crystal orientation is rotated by 105° toward the +Y axis direction. Thus, the vibration direction 60 of the thickness-shear vibration and the direction perpendicular thereto become the planar direction of the piezoelectric layer 14. The +Z direction is preferably within a range of ±5° from a direction in which the +Z axis direction is rotated by 105° toward the +Y axis direction, and more preferably within a range of ±1°. The Euler's angle is preferably (0°±5°, −105°±5°, θ°±5°).

[Simulation]

Simulation was performed on the first embodiment and the first comparative example. In the first embodiment, the thickness T16 of the upper electrode 16 is larger than the thickness T12 of the lower electrode 12, as described above. On the other hand, in the first comparative example, the thickness T16 of the upper electrode 16 and the thickness T12 of the lower electrode 12 have the same thickness. The simulation conditions are as follows.

### Conditions Common to the First Embodiment and First Comparative Example

Wavelength λ, of the acoustic wave: Twice the thickness T14 of the piezoelectric layer 14
Additional film 28: Silicon oxide film having the thickness T28 of 65 nm
Piezoelectric layer 14: Lithium niobate layer having the thickness T14 of 470 nm (the X axis direction of the crystal orientation is the X direction, and the direction in which the +Z axis direction is rotated by 105° toward the +Y axis direction is the +Z direction)
Lower electrode 12: Aluminum film having the thickness T12 of 47 nm
Low acoustic impedance film 31: Silicon oxide (SiO₂) film having the thickness T31 of 192 nm
High acoustic impedance film 32: Tungsten film having the thickness T32 of 151 nm
Condition in X direction: The width of the resonance region 50 in the X direction is set to 30λ
Condition in Y direction: The width in the Y direction is 0.5λ, and the boundary condition is infinitely continuous

### Conditions of First Embodiment

Upper electrode 16: Aluminum film having the thickness T16 of 100 nm

### Condition of First Comparative Example

Upper electrode 16: Aluminum film having the thickness T16 of 47 nm

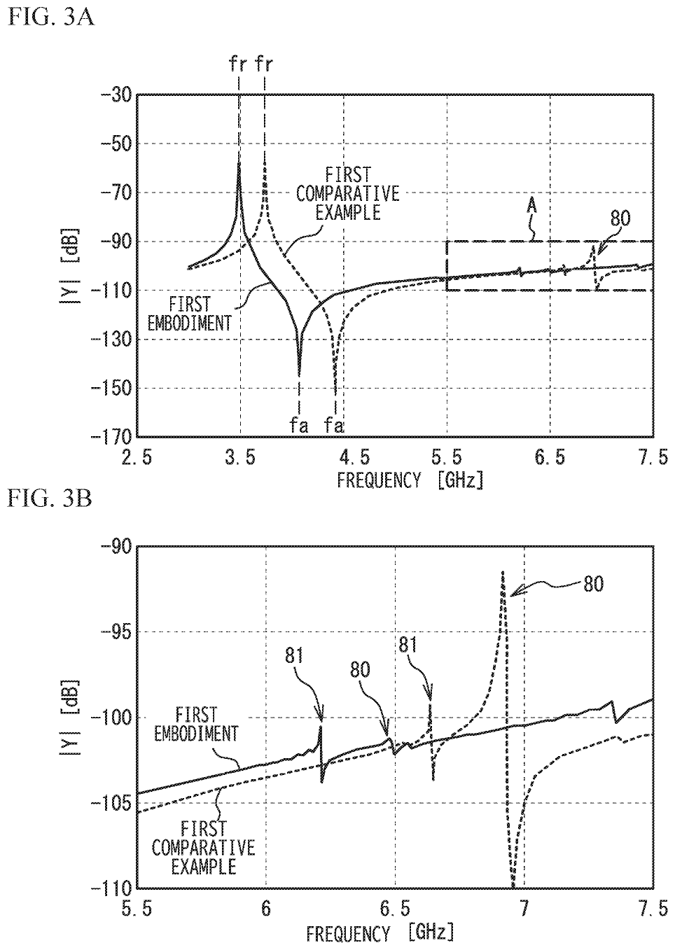

FIG. 3A is a diagram illustrating an absolute value Y of admittance with respect to a frequency of the first embodiment and a first comparative example in simulation. FIG. 3B is an enlarged view of a region A in FIG. 3A. At the absolute value Y of admittance, peaks of resonance frequency fr and antiresonance frequency fa are observed. As illustrated in FIGS. 3A and 3B, in the first comparative example, a spurious 80 occurred at a frequency higher than the antiresonance frequency fa. The magnitude of the spurious 80 in the first comparative example was about 18 dB. On the other hand, in the first embodiment, the spurious 80 at a frequency higher than the antiresonance frequency fa was reduced as compared with the first comparative example. The magnitude of the spurious 80 in the first embodiment was about 1 dB. As will be described in detail later, it is considered that the spurious 80 is caused by the second harmonic of the thickness-shear vibration. In the first comparative example and the first embodiment, a spurious 81 occurs at a frequency lower than the spurious 80. It is considered that the spurious 81 is caused by the second harmonic of the thickness longitudinal vibration.

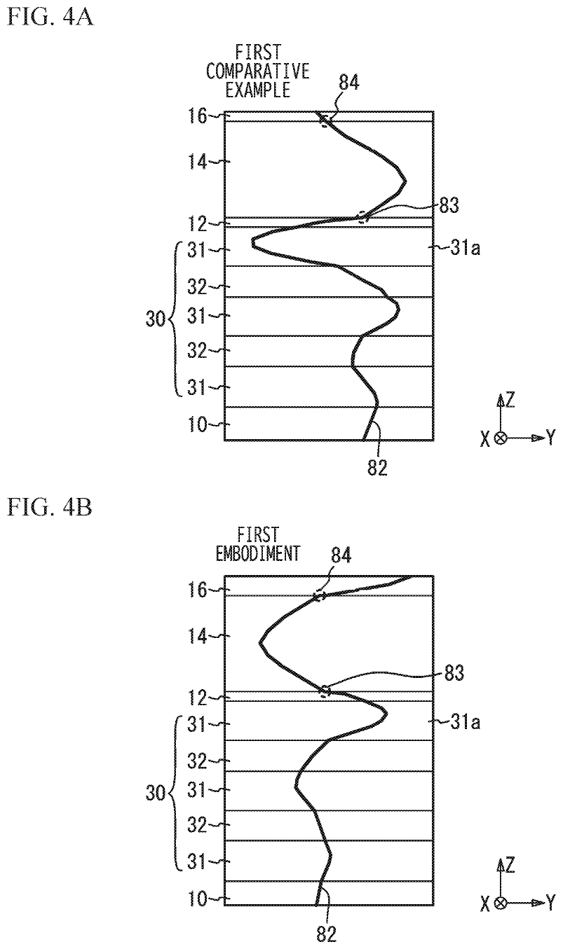

FIG. 4A is a diagram illustrating displacement of second harmonic vibration 82 of the thickness-shear vibration of the first comparative example in the simulation. FIG. 4B is a diagram illustrating displacement of the second harmonic vibration 82 of the thickness-shear vibration of the first embodiment in the simulation. In FIGS. 4A and 4B, the lateral direction is the displacement direction of the second harmonic vibration 82, and it is illustrated that the larger the amplitude of the second harmonic vibration 82 in the lateral direction is, the larger the displacement is. The longitudinal direction is a lamination direction of the acoustic reflection film 30, the lower electrode 12, the piezoelectric layer 14 and the upper electrode 16 formed on the substrate 10. In FIG. 4B, for clarity of illustration, the scale in the lateral direction is three times larger than that in FIG. 4A. In FIGS. 4A and 4B, the direction of displacement of the second harmonic vibration 82 is opposite to that of the second harmonic vibration 82 because the case where the amplitude of the input high-frequency signal is opposite to that of the second harmonic vibration 82 is illustrated.

As illustrated in FIG. 4A, in the first comparative example, the second harmonic vibration 82 was a result of positional displacement between a boundary 83 between the lower electrode 12 and the piezoelectric layer 14 and a boundary 84 between the upper electrode 16 and the piezoelectric layer 14. Since the acoustic reflection film 30 is designed for the fundamental wave, the acoustic reflection film 30 is hard to function as a reflection film for the second harmonic. Therefore, the second harmonic is reflected by the air layer above the upper electrode 16 on the side of the upper electrode 16, while it is hard to be reflected by the acoustic reflection film 30 on the side of the lower electrode 12, so that it is considered that the upper and lower balance is lost.

As illustrated in FIG. 4B, in the first embodiment, the difference between the displacement of the second harmonic vibration 82 at the boundary 83 between the lower electrode 12 and the piezoelectric layer 14 and the displacement of the second harmonic vibration 82 at the boundary 84 between the upper electrode 16 and the piezoelectric layer 14 is reduced, compared with the first comparative example. This may be because the balance of the second harmonic between the upper electrode 16 side and the lower electrode 12 side is improved by making the thickness T16 of the upper electrode 16 thicker than the thickness T12 of the lower electrode 12.

Thus, in the first comparative example, since the difference between the displacement of the second harmonic vibration 82 at the boundary 83 between the lower electrode 12 and the piezoelectric layer 14 and the displacement of the second harmonic vibration 82 at the boundary 84 between the upper electrode 16 and the piezoelectric layer 14 is large, it is considered that the large spurious 80 occurs as illustrated in FIG. 3B. On the other hand, in the first embodiment, since the difference between the displacement of the second harmonic vibration 82 at the boundary 83 between the lower electrode 12 and the piezoelectric layer 14 and the displacement of the second harmonic vibration 82 at the boundary 84 between the upper electrode 16 and the piezoelectric layer 14 is reduced, it is considered that the spurious 80 is reduced as illustrated in FIG. 3B. Thus, it is considered that the spurious 80 occurred in the first comparative example and the first embodiment is caused by the second harmonic of the thickness-shear vibration.

Table 1 illustrates the thickness (average thickness) of each layer, the material and density of each layer, and the weight per unit area of each layer for the first comparative example and first embodiment in the simulations. The weight per unit area is calculated by “average thickness×density”. Since the additional film 28 is provided in the edge region 52 of the resonance region 50 and has a width sufficiently narrow with respect to the resonance region 50, the additional film 28 has a small influence on the second harmonic. For this reason, the additional film 28 is omitted in Table 1 (the same to the following similar tables).

TABLE 1

| | | | | | WEIGHT PER UNIT | |
|---|---|---|---|---|---|---|
| | THICKNESS [nm] | | | | AREA [g/m²] | |
| | FIRST | | | | FIRST | |
| | COMPARATIVE | FIRST | | DENSITY | COMPARATIVE | FIRST |
| | EXAMPLE | EMBODIMENT | MATERIAL | [kg/m³] | EXAMPLE | EMBODIMENT |
| UPPER | 47 | 100 | ALUMINUM | 2700 | 0.1269 | 0.27 |
| ELECTRODE | | | | | | |
| PIEZOELECTRIC | 470 | 470 | LITHIUM | 4650 | 2.1855 | 2.1855 |
| LAYER | | | NIOBATE | | | |
| LOWER | 47 | 47 | ALUMINUM | 2700 | 0.1269 | 0.1269 |
| ELECTRODE | | | | | | |
| LOW ACOUSTIC | 192 | 192 | SILICON | 2200 | 0.4224 | 0.4224 |
| IMPEDANCE FILM | | | OXIDE | | | |
| HIGH ACOUSTIC | 151 | 151 | TUNGSTEN | 17800 | 2.6878 | 2.6878 |
| IMPEDANCE FILM | | | | | | |
| LOW ACOUSTIC | 192 | 192 | SILICON | 2200 | 0.4224 | 0.4224 |
| IMPEDANCE FILM | | | OXIDE | | | |
| HIGH ACOUSTIC | 151 | 151 | TUNGSTEN | 17800 | 2.6878 | 2.6878 |
| IMPEDANCE FILM | | | | | | |
| LOW ACOUSTIC | 192 | 192 | SILICON | 2200 | 0.4224 | 0.4224 |
| IMPEDANCE FILM | | | OXIDE | | | |

As illustrated in Table 1, in the first comparative example, since the upper electrode 16 is the aluminum film having the thickness T16 of 47 nm, the weight per unit area is 0.1269 g/m². Since the piezoelectric layer 14 is the lithium niobate layer having the thickness T14 of 470 nm, the weight per unit area is 2.1855 g/m². Since the lower electrode 12 is the aluminum film having the thickness T12 of 47 nm, the weight per unit area is 0.1269 g/m². Since the low acoustic impedance film 31 is the silicon oxide film having the thickness T31 of 192 nm, the weight per unit area is 0.4224 g/m². Since the high acoustic impedance film 32 is the tungsten film having the thickness T32 of 151 nm, the weight per unit area is 2.6878 g/m².

On the other hand, in the first embodiment, since the upper electrode 16 is the aluminum film having the thickness T16 of 100 nm, the weight per unit area is 0.27 g/m². The weight per unit area of the piezoelectric layer 14, the lower electrode 12, the low acoustic impedance film 31, and the high acoustic impedance film 32 of the first embodiment is the same as that of the first comparative example.

As illustrated in FIGS. 4A and 4B, among the plurality of low acoustic impedance films 31 and the plurality of high acoustic impedance films 32 constituting the acoustic reflection film 30, the low acoustic impedance film 31 closest to the lower electrode 12 has a larger displacement of the second harmonic vibration 82 than other films. Therefore, it is considered that the low acoustic impedance film 31 closest to the lower electrode 12 has a large influence on the second harmonic. Hereinafter, the low acoustic impedance film 31 closest to the lower electrode 12 is referred to as a low acoustic impedance film 31a.

In the first embodiment, as illustrated in FIG. 4B, the difference between the displacement of the second harmonic vibration 82 at the boundary 83 between the lower electrode 12 and the piezoelectric layer 14 and the displacement of the second harmonic vibration 82 at the boundary 84 between the upper electrode 16 and the piezoelectric layer 14 is small. Since the acoustic wave is affected by the weight of each layer, it is considered that the weight on the upper electrode 16 side and the weight on the lower electrode 12 side are approximately the same for the second harmonic because the difference between the displacements of the second harmonic vibration 82 at the boundary 83 and the boundary 84 is small.

Since the low acoustic impedance film 31a closest to the lower electrode 12 has a large influence on the second harmonic, the weight on the lower electrode 12 side is considered to be the sum of the weight per unit area of the lower electrode 12 and the weight per unit area of the low acoustic impedance film 31a. Since the additional film 28 has a small influence on the second harmonic, the weight on the upper electrode 16 side is considered to be the weight per unit area of the upper electrode 16. In this case, the weight per unit area of the upper electrode 16 is 0.27 g/m², and the sum of the weight per unit area of the lower electrode 12 and the weight per unit area of the low acoustic impedance film 31a is 0.1269+0.4224=0.5493 g/m², so that the weight on the upper electrode 16 side and the weight on the lower electrode 12 side are greatly different from each other. Therefore, it is considered that only a part of the low acoustic impedance film 31a influences the second harmonic, and the following equation (1) is assumed regarding the weight per unit area of each layer in the resonance region 50.

Weight per unit area of upper electrode 16=weight per unit area of lower electrode 12+(weight per unit area of low acoustic impedance film 31a×α) (1)

In the first embodiment, 0.27=0.1269+(0.4224×α) is established from the equation (1), and a is about 0.34. Therefore, it is considered that about 66 nm, which is 0.34 times of the thickness of 192 nm of the low acoustic impedance film 31a, greatly affects the second harmonic.

The above simulation was performed for the case where the target frequency band was 3.7 GHz and the lower electrode 12 and the upper electrode 16 were aluminum films. The following tables illustrate the simulation results obtained when frequency bands, or materials for the lower electrode 12 and the upper electrode 16 are different from each other. Table 2 illustrates the thickness (average thickness) of each layer, the material and density of each layer, and the weight per unit area of each layer for the first embodiment in the target frequency band of 3.0 GHz, and Table 3 illustrates the thickness (average thickness) of each layer, the material and density of each layer, and the weight per unit area of each layer for the first embodiment in the target frequency band of 4.7 GHz.

TABLE 2

| | 3.0 GHz BAND | | | |
|---|---|---|---|---|
| | THICKNESS | | DENSITY | WEIGHT PER UNIT |
| | [nm] | MATERIAL | [kg/m³] | AREA [g/m²] |
| UPPER | 125 | ALUMINUM | 2700 | 0.3375 |
| ELECTRODE | | | | |
| PIEZOELECTRIC | 587.5 | LITHIUM | 4650 | 2.7131875 |
| LAYER | | NIOBATE | | |
| LOWER | 58.7 | ALUMINUM | 2700 | 0.15849 |
| ELECTRODE | | | | |
| LOW ACOUSTIC | 240 | SILICON | 2200 | 0.528 |
| IMPEDANCE FILM | | OXIDE | | |
| HIGH ACOUSTIC | 190 | TUNGSTEN | 17800 | 3.382 |
| IMPEDANCE FILM | | | | |
| LOW ACOUSTIC | 240 | SILICON | 2200 | 0.528 |
| IMPEDANCE FILM | | OXIDE | | |
| HIGH ACOUSTIC | 190 | TUNGSTEN | 17800 | 3.382 |
| IMPEDANCE FILM | | | | |
| LOW ACOUSTIC | 240 | SILICON | 2200 | 0.528 |
| IMPEDANCE FILM | | OXIDE | | |

As illustrated in Table 2, in the target frequency band of 3.0 GHz, when the thickness T16 of the upper electrode 16 is 125 nm, the thickness T14 of the piezoelectric layer 14 is 587.5 nm, the thickness T12 of the lower electrode 12 is 58.7 nm, the thickness T31 of the low acoustic impedance film 31 is 240 nm, and the thickness T32 of the high acoustic impedance film 32 is 190 nm, the spurious 80 caused by the second harmonic of the thickness-shear vibration is reduced. In this case, 0.3375=0.15849+(0.528×α) is established from the equation (1), and a is about 0.34. Therefore, it is considered that a thickness of about 82 nm, which is 0.34 times of the thickness of the low acoustic impedance film 31a of 240 nm, greatly affects the second harmonic.

TABLE 3

| | 4.7 GHz BAND | | | |
|---|---|---|---|---|
| | THICKNESS | | DENSITY | WEIGHT PER UNIT |
| | [nm] | MATERIAL | [kg/m³] | AREA [g/m²] |
| UPPER | 80 | ALUMINUM | 2700 | 0.216 |
| ELECTRODE | | | | |
| PIEZOELECTRIC | 366 | LITHIUM | 4650 | 1.7019 |
| LAYER | | NIOBATE | | |
| LOWER | 36 | ALUMINUM | 2700 | 0.0972 |
| ELECTRODE | | | | |
| LOW ACOUSTIC | 150 | SILICON | 2200 | 0.33 |
| IMPEDANCE FILM | | OXIDE | | |
| HIGH ACOUSTIC | 118 | TUNGSTEN | 17800 | 2.1004 |
| IMPEDANCE FILM | | | | |
| LOW ACOUSTIC | 150 | SILICON | 2200 | 0.33 |
| IMPEDANCE FILM | | OXIDE | | |
| HIGH ACOUSTIC | 118 | TUNGSTEN | 17800 | 2.1004 |
| IMPEDANCE FILM | | | | |
| LOW ACOUSTIC | 150 | SILICON | 2200 | 0.33 |
| IMPEDANCE FILM | | OXIDE | | |

As illustrated in Table 3, in the target frequency band of 4.7 GHz, when the thickness T16 of the upper electrode 16 is 80 nm, the thickness T14 of the piezoelectric layer 14 is 366 nm, the thickness T12 of the lower electrode 12 is 36 nm, the thickness T31 of the low acoustic impedance film 31 is 150 nm, and the thickness T32 of the high acoustic impedance film 32 is 118 nm, the spurious 80 caused by the second harmonic of the thickness-shear vibration is reduced. In this case, 0.216=0.0972+(0.33×α) is established from the equation (1), and α is 0.36. Therefore, it is considered that a thickness of 54 nm, which is 0.36 times of the thickness of 150 nm of the low acoustic impedance film 31a closest to the lower electrode 12, greatly affects the second harmonic.

Table 4 illustrates the thickness (average thickness) of each layer, the material and density of each layer, and the weight per unit area of each layer for the first embodiment when a titanium film is used for the lower electrode 12 and the upper electrode 16, and Table 5 illustrates the thickness (average thickness) of each layer, the material and density of each layer, and the weight per unit area of each layer for the first embodiment when a ruthenium film is used for the lower electrode 12 and the upper electrode 16.

TABLE 4

| | 3.7 GHz BAND | | | |
|---|---|---|---|---|
| | THICKNESS | | DENSITY | WEIGHT PER UNIT |
| | [nm] | MATERIAL | [kg/m³] | AREA [g/m²] |
| UPPER | 80 | TITANIUM | 4506 | 0.36048 |
| ELECTRODE | | | | |
| PIEZOELECTRIC | 470 | LITHIUM | 4650 | 2.1855 |
| LAYER | | NIOBATE | | |
| LOWER | 47 | TITANIUM | 4506 | 0.211782 |
| ELECTRODE | | | | |
| LOW ACOUSTIC | 192 | SILICON | 2200 | 0.4224 |
| IMPEDANCE FILM | | OXIDE | | |
| HIGH ACOUSTIC | 151 | TUNGSTEN | 17800 | 2.6878 |
| IMPEDANCE FILM | | | | |
| LOW ACOUSTIC | 192 | SILICON | 2200 | 0.4224 |
| IMPEDANCE FILM | | OXIDE | | |
| HIGH ACOUSTIC | 151 | TUNGSTEN | 17800 | 2.6878 |
| IMPEDANCE FILM | | | | |
| LOW ACOUSTIC | 192 | SILICON | 2200 | 0.4224 |
| IMPEDANCE FILM | | OXIDE | | |

As illustrated in Table 4, when the titanium film is used for the lower electrode 12 and the upper electrode 16, the thickness T16 of the upper electrode 16 is 80 nm, the thickness T14 of the piezoelectric layer 14 is 470 nm, the thickness T12 of the lower electrode 12 is 47 nm, the thickness T31 of the low acoustic impedance film 31 is 192 nm, and the thickness T32 of the high acoustic impedance film 32 is 151 nm, the spurious 80 caused by the second harmonic of the thickness-shear vibration is reduced. In this case, 0.36048=0.211782+(0.4224×α) is established from the equation (1), and α is about 0.35. Therefore, it is considered that a thickness of about 68 nm, which is 0.35 times of the thickness of 192 nm of the low acoustic impedance film 31a closest to the lower electrode 12, greatly affects the second harmonic.

TABLE 5

| | 3.7 GHz BAND | | | |
|---|---|---|---|---|
| | THICKNESS | | DENSITY | WEIGHT PER UNIT |
| | [nm] | MATERIAL | [kg/m³] | AREA [g/m²] |
| UPPER | 58 | RUTHENIUM | 12370 | 0.71746 |
| ELECTRODE | | | | |
| PIEZOELECTRIC | 470 | LITHIUM | 4650 | 2.1855 |
| LAYER | | NIOBATE | | |
| LOWER | 47 | RUTHENIUM | 12370 | 0.58139 |
| ELECTRODE | | | | |
| LOW ACOUSTIC | 192 | SILICON | 2200 | 0.4224 |
| IMPEDANCE FILM | | OXIDE | | |
| HIGH ACOUSTIC | 151 | TUNGSTEN | 17800 | 2.6878 |
| IMPEDANCE FILM | | | | |
| LOW ACOUSTIC | 192 | SILICON | 2200 | 0.4224 |
| IMPEDANCE FILM | | OXIDE | | |
| HIGH ACOUSTIC | 151 | TUNGSTEN | 17800 | 2.6878 |
| IMPEDANCE FILM | | | | |
| LOW ACOUSTIC | 192 | SILICON | 2200 | 0.4224 |
| IMPEDANCE FILM | | OXIDE | | |

As illustrated in Table 5, when the ruthenium film is used for the lower electrode 12 and the upper electrode 16, the thickness T16 of the upper electrode 16 was 58 nm, the thickness T14 of the piezoelectric layer 14 was 470 nm, the thickness T12 of the lower electrode 12 was 47 nm, the thickness T31 of the low acoustic impedance film 31 was 192 nm, and the thickness T32 of the high acoustic impedance film 32 was 151 nm, the spurious 80 caused by the second harmonic of the thickness-shear vibration is reduced. In this case, 0.71746=0.58139+(0.4224×α) is established from the equation (1), and α is about 0.32. Therefore, it is considered that a thickness of about 62 nm, which is 0.32 times of the thickness of 192 nm of the low acoustic impedance film 31a closest to the lower electrode 12, greatly affects the second harmonic.

As described above, even when the target frequency bands, and the materials of the lower electrode 12 and the upper electrode 16 are different, the value of α in the equation (1) is almost the same.

Next, the relationship between the thickness T16 of the upper electrode 16 and the magnitude of the spurious 80 was obtained by simulation for the case where a ruthenium film was used for the lower electrode 12 and the upper electrode 16 in the target frequency band of 3.7 GHz. The simulation conditions are as follows.
Wavelength λ of acoustic wave: Twice thickness T14 of piezoelectric layer 14
Additional film 28: Silicon oxide film having thickness T28 of 65 nm
Upper electrode 16: Ruthenium film having thickness T16 between 47 nm and 80 nm
Piezoelectric layer 14: Lithium niobate layer having thickness T14 of 470 nm (the X axis direction of the crystal orientation is the X direction, and the direction in which the +Z axis direction is rotated by 105° toward the +Y axis direction is the +Z direction)
Lower electrode 12: Ruthenium film having thickness T12 of 47 nm
Low acoustic impedance film 31: Silicon oxide (SiO₂) film having thickness T31 of 192 nm
High acoustic impedance film 32: Tungsten film having thickness T32 of 151 nm
Condition in X direction: Width of resonance region 50 in X direction is set to 30λ
Condition in Y direction: Width in Y direction is 0.5λ, and boundary condition is infinitely continuous

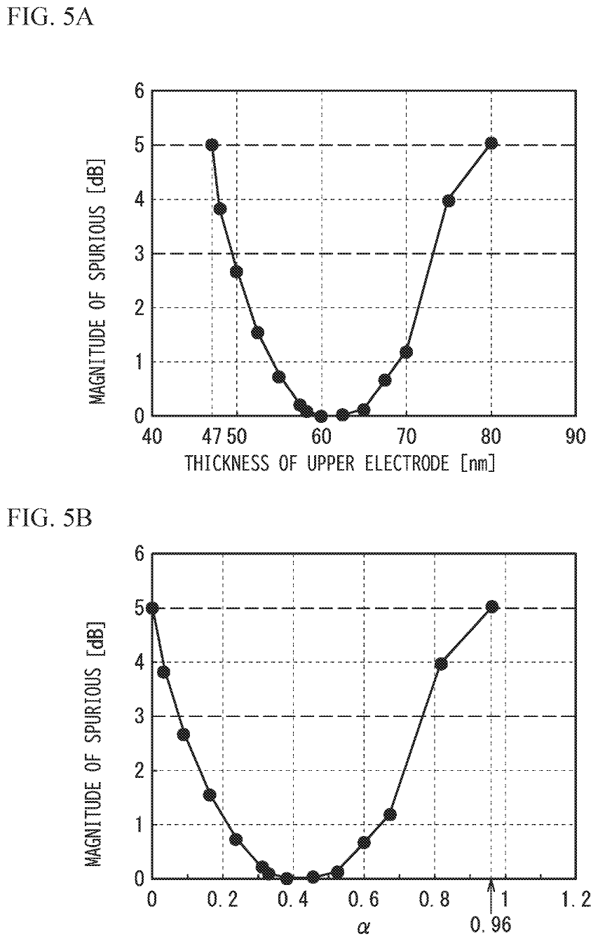

FIG. 5A is a diagram illustrating a simulation result of the magnitude of the spurious 80 caused by the second harmonic of the thickness-shear vibration with respect to the thickness T16 of the upper electrode 16. FIG. 5B is a diagram illustrating a case where the horizontal axis in FIG. 5A is converted into α in equation (1). In FIG. 5B, when α=0, the thickness T12 of the lower electrode 12 and the thickness T16 of the upper electrode 16 are both equal to 47 nm.

As illustrated in FIG. 5A, when the thickness T16 of the upper electrode 16 is larger than 47 nm and smaller than 80 nm, the spurious 80 is reduced as compared with when the thickness T16 of the upper electrode 16 is equal to the thickness T12 of the lower electrode 12, which is 47 nm. The spurious 80 decreases as the thickness T16 of the upper electrode 16 increases until the thickness T16 of the upper electrode 16 is around 60 nm, but the spurious 80 increases as the thickness T16 of the upper electrode 16 increases when the thickness T16 exceeds 60 nm.

As illustrated in FIG. 5B, when the value of α in the equation (1) is larger than 0 and smaller than 0.96, the spurious 80 is reduced as compared with the case where α is 0. The spurious 80 decreases as α increases up to about 0.4, but when a exceeds 0.4, the spurious 80 increases as α increases.

Accordingly, in the first embodiment, the thickness of the upper electrode 16 is adjusted so that the value of α obtained from the equation (1) becomes 0<α<0.96. Thus, the spurious 80 can be reduced.

FIGS. 5A and 5B are simulation results when the ruthenium film is used for the lower electrode 12 and the upper electrode 16 in the target frequency band of 3.7 GHz. However, as illustrated in Tables 2 to 5, the value of a hardly changes even when the target frequency bands, and the materials of the lower electrode 12 and the upper electrode 16 are different, so that it is considered that the spurious 80 can be reduced by setting the value of a to 0<α<0.96 even when the frequency bands and the materials are different.

[Modification 1]

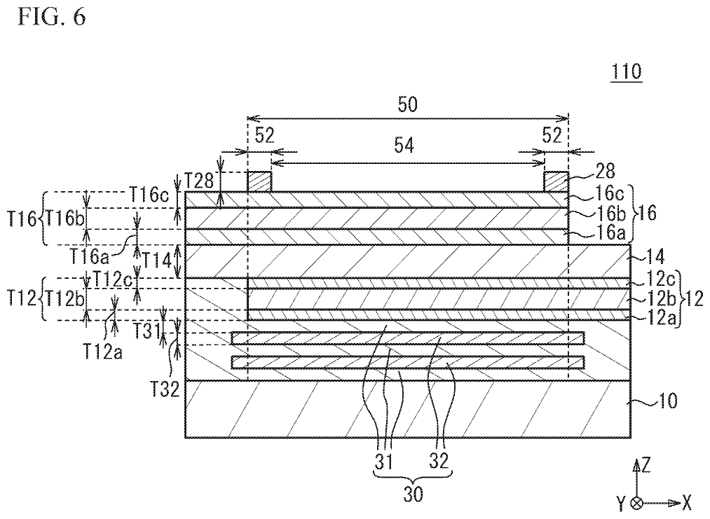

FIG. 6 is a cross-sectional view of an acoustic wave device 110 according to a first modification of the first embodiment. As illustrated in FIG. 6, in the acoustic wave device 110, the lower electrode 12 has a first layer 12a, a second layer 12b provided on the first layer 12a, and α third layer 12c provided on the second layer 12b. The upper electrode 16 has a first layer 16a, a second layer 16b provided on the first layer 16a, and a third layer 16c provided on the second layer 16b. For example, a thickness T16a of the first layer 16a of the upper electrode 16 is larger than a thickness T12a of the first layer 12a of the lower electrode 12. A thickness T16b of the second layer 16b of the upper electrode 16 is substantially equal to a thickness T12b of the second layer 12b of the lower electrode 12. A thickness T16c of the third layer 16c of the upper electrode 16 is larger than a thickness T12c of the third layer 12c of the lower electrode 12. Thus, the thickness T16 of the upper electrode 16 is larger than the thickness T12 of the lower electrode 12. Since other configurations are the same as those of the first embodiment, description thereof will be omitted.

[Simulation]

Simulation was performed on the first modification of the first embodiment and the second comparative example. As described above, in the upper electrode 16 and the lower electrode 12 according to the first modification of the first embodiment, the thickness T16a of the first layer 16a is thicker than the thickness T12a of the first layer 12a, the thickness T16b of the second layer 16b is the same as the thickness T12b of the second layer 12b, and the thickness T16c of the third layer 16c is thicker than the thickness T12c of the third layer 12c. On the other hand, in the upper electrode 16 and the lower electrode 12 according to the second comparative example, the thickness T16a of the first layer 16a and the thickness T12a of the first layer 12a are the same as each other, the thickness T16b of the second layer 16b and the thickness T12b of the second layer 12b are the same as each other, and the thickness T16c of the third layer 16c and the thickness T12c of the third layer 12c are the same as each other.

The simulation conditions are as follows.

Conditions Common to Modification 1 and Comparative Example 2 of Embodiment 1
Wavelength λ, of acoustic wave: Twice thickness T14 of piezoelectric layer 14
Additional film 28: Silicon oxide film having thickness T28 of 65 nm
Piezoelectric layer 14: Lithium niobate layer having thickness T14 of 470 nm (the X axis direction of the crystal orientation is the X direction, and the direction in which the +Z axis direction is rotated by 105° toward the +Y axis direction is the +Z direction)
Third layer 12c of lower electrode 12: Aluminum film having thickness T12c of 23.5 nm
Second layer 12b of lower electrode 12: Titanium film having thickness T12b of 52 nm
First layer 12a of lower electrode 12: Aluminum film having thickness T12a of 23.5 nm
Low acoustic impedance film 31: Silicon oxide (SiO₂) film having thickness T31 of 192 nm
High acoustic impedance film 32: Tungsten film having thickness T32 of 151 nm
Condition in X direction: Width of resonance region 50 in X direction is set to 30λ
Condition in Y direction: Width in Y direction is 0.5λ, and boundary condition is infinitely continuous

Condition of First modification of First embodiment
Third layer 16c of upper electrode 16: Aluminum film having thickness T16c of 47.5 nm
Second layer 16b of upper electrode 16: Titanium film having thickness T16b of 52 nm

First layer 16a of upper electrode 16: Aluminum film having thickness T16a of 47.5 nm Condition of Second comparative example
Third layer 16c of upper electrode 16: Aluminum film having thickness T16c of 23.5 nm
Second layer 16b of upper electrode 16: Titanium film having thickness T16b of 52 nm
First layer 16a of upper electrode 16: Aluminum film having thickness T16a of 23.5 nm

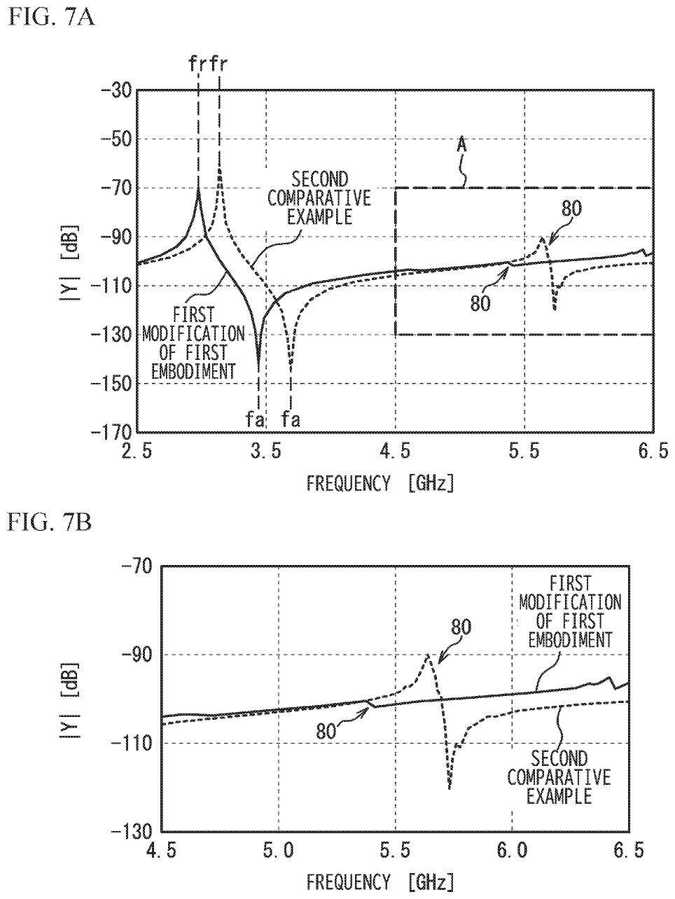

FIG. 7A is a diagram illustrating an absolute value Y of admittance with respect to a frequency of the first modification of the first embodiment and the second comparative example in the simulation. FIG. 7B is an enlarged view of a region A in FIG. 7A. As illustrated in FIGS. 7A and 7B, in the second comparative example, the spurious 80 occurs at a frequency higher than the antiresonance frequency fa. On the other hand, in the first modification of the first embodiment, the spurious 80 at the frequency higher than the antiresonance frequency fa is reduced as compared with the second comparative example.

Thus, even when the lower electrode 12 and the upper electrode 16 are laminated films composed of a plurality of layers, the spurious 80 is reduced by making the thickness T16 of the upper electrode 16 larger than the thickness T12 of the lower electrode 12.

Table 6 illustrates the thickness (average thickness) of each layer, the material and density of each layer, and the weight per unit area of each layer for the first modification of the first embodiment in the simulation.

TABLE 6

| | | 3. 7 GHz BAND | | | |
|---|---|---|---|---|---|
| | | THICKNESS | | DENSITY | WEIGHT PER UNIT |
| | | [nm] | MATERIAL | [kg/m³] | AREA [g/m²] |
| UPPER | THIRD | 47.5 | ALUMINUM | 2700 | 0.12825 |
| ELECTRODE | LAYER | | | | |
| | SECOND | 52 | TITANIUM | 4506 | 0.234312 |
| | LAYER | | | | |
| | FIRST | 47.5 | ALUMINUM | 2700 | 0.12825 |
| | LAYER | | | | |
| PIEZOELECTRIC | | 470 | LITHIUM | 4650 | 2.1855 |
| LAYER | | | NIOBATE | | |
| LOWER | THIRD | 23.5 | ALUMINUM | 2700 | 0.06345 |
| ELECTRODE | LAYER | | | | |
| | SECOND | 52 | TITANIUM | 4506 | 0.234312 |
| | LAYER | | | | |
| | FIRST | 23.5 | ALUMINUM | 2700 | 0.06345 |
| | LAYER | | | | |

| | | | | |
|---|---|---|---|---|
| LOW ACOUSTIC | 192 | SILICON | 2200 | 0.4224 |
| IMPEDANCE FILM | | OXIDE | | |
| HIGH ACOUSTIC | 151 | TUNGSTEN | 17800 | 2.6878 |
| IMPEDANCE FILM | | | | |
| LOW ACOUSTIC | 192 | SILICON | 2200 | 0.4224 |
| IMPEDANCE FILM | | OXIDE | | |
| HIGH ACOUSTIC | 151 | TUNGSTEN | 17800 | 2.6878 |
| IMPEDANCE FILM | | | | |
| LOW ACOUSTIC | 192 | SILICON | 2200 | 0.4224 |
| IMPEDANCE FILM | | OXIDE | | |

As illustrated in Table 6, in the first modification of the first embodiment, (0.12825+0.234312+0.12825)=(0.06345+0.234312+0.06345)+(0.4224×α) is established from the equation (1), and α is about 0.31. Therefore, it is considered that a thickness of about 60 nm, which is 0.31 times of the thickness of 192 nm of the low acoustic impedance film 31a, greatly affects the second harmonic. Thus, even when the lower electrode 12 and the upper electrode 16 are the laminated films composed of the plurality of layers, the value of α in the equation (1) is almost the same as the value of a when the lower electrode 12 and the upper electrode 16 are not the laminated films. Therefore, also in the first modification of the first embodiment, it is considered that the spurious 80 can be reduced by setting the value of a to 0<α<0.96.

[Second Modification]

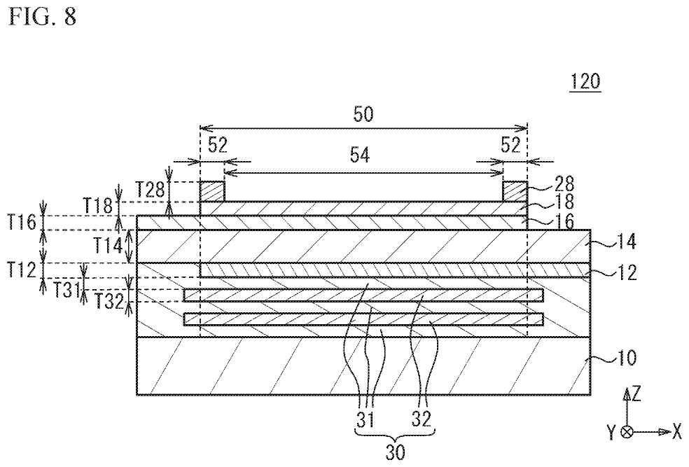

FIG. 8 is a cross-sectional view of an acoustic wave device 120 according to a second modification of the first embodiment. As illustrated in FIG. 8, in the acoustic wave device 120, an insulating film 18 is provided on the upper electrode 16. The insulating film 18 is provided on the upper electrode 16 from the central region 54 to the edge region 52 of the resonance region 50. That is, the insulating film 18 is provided on the upper electrode 16 over the entire resonance region 50. The additional film 28 is provided on the insulating film 18. The insulating film 18 is, for example, a silicon oxide film or a silicon nitride film. The thickness T18 of the insulating film 18 is, for example, about 30 nm to 100 nm. The thickness T16 of the upper electrode 16 and the thickness T12 of the lower electrode 12 are substantially the same. Since other configurations are the same as those of the first embodiment, description thereof will be omitted.

[Simulation]

A simulation was performed on the second modification of the first embodiment. The simulation conditions are as follows, which are the same as those of the first comparative example except for the insulating film 18.

Condition of Second modification of First embodiment
Wavelength λ of acoustic wave: twice thickness T14 of piezoelectric layer 14
Additional film 28: Silicon oxide film having thickness T28 of 65 nm
Insulating film 18: Silicon oxide (SiO₂) film having thickness T18 of 65 nm
Upper electrode 16: Aluminum film having thickness T16 of 47 nm
Piezoelectric layer 14: Lithium niobate layer having thickness T14 of 470 nm (the X axis direction of the crystal orientation is the X direction, and the direction in which the +Z axis direction is rotated by 105° toward the +Y axis direction is the +Z direction)
Lower electrode 12: Aluminum film having thickness T12 of 47 nm
Low acoustic impedance film 31: Silicon oxide (SiO₂) film having thickness T31 of 192 nm
High acoustic impedance film 32: Tungsten film having thickness T32 of 151 nm
Condition in X direction: Width of resonance region 50 in X direction is set to 30λ
Condition in Y direction: Width in Y direction is 0.5λ, and boundary condition is infinitely continuous

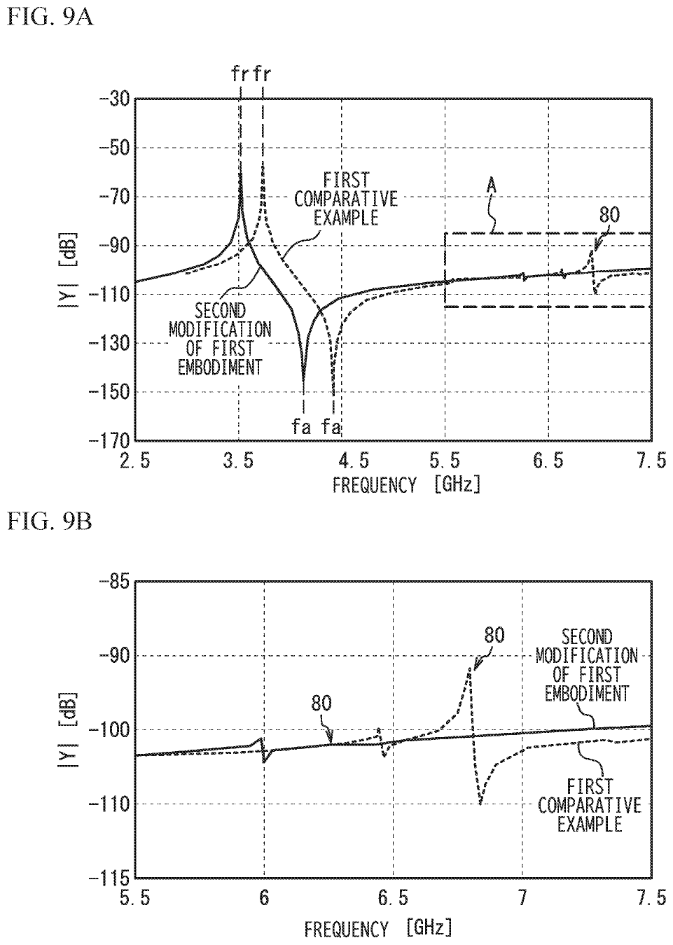

FIG. 9A is a diagram illustrating an absolute value Y of admittance to a frequency of the second modification of the first embodiment and the first comparative example in the simulation. FIG. 9B is an enlarged view of a region A in FIG. 9A. As illustrated in FIGS. 9A and 9B, in the second modification of the first embodiment, the spurious 80 is reduced as compared with the first comparative example. Thus, even when the thickness T16 of the upper electrode 16 and the thickness T12 of the lower electrode 12 are equal to each other, the spurious 80 is reduced by providing the insulating film 18 on the upper electrode 16.

Table 7 illustrates the thickness (average thickness) of each layer, the material and density of each layer, and the weight per unit area of each layer for the second modification of the first embodiment in the simulation.

TABLE 7

| | 3.7 GHz BAND | | | |
|---|---|---|---|---|
| | THICKNESS | | DENSITY | WEIGHT PER UNIT |
| | [nm] | MATERIAL | [kg/m³] | AREA [g/m²] |
| INSULATING | 65 | SILICON | 2200 | 0.143 |
| FILM | | OXIDE | | |
| UPPER | 47 | ALUMINUM | 2700 | 0.1269 |
| ELECTRODE | | | | |
| PIEZOELECTRIC | 470 | LITHIUM | 4650 | 2.1855 |
| LAYER | | NIOBATE | | |
| LOWER | 47 | ALUMINUM | 2700 | 0.1269 |
| ELECTRODE | | | | |
| LOW ACOUSTIC | 192 | SILICON | 2200 | 0.4224 |
| IMPEDANCE FILM | | OXIDE | | |
| HIGH ACOUSTIC | 151 | TUNGSTEN | 17800 | 2.6878 |
| IMPEDANCE FILM | | | | |
| LOW ACOUSTIC | 192 | SILICON | 2200 | 0.4224 |
| IMPEDANCE FILM | | OXIDE | | |
| HIGH ACOUSTIC | 151 | TUNGSTEN | 17800 | 2.6878 |
| IMPEDANCE FILM | | | | |
| LOW ACOUSTIC | 192 | SILICON | 2200 | 0.4224 |
| IMPEDANCE FILM | | OXIDE | | |

Since the second modification of the first embodiment is different from the first embodiment and the first modification of the first embodiment in that the insulating film 18 is provided on the upper electrode 16, the following equation (2) regarding the weight per unit area of each layer in the resonance region 50 is assumed instead of the above equation (1).

Weight per unit area of upper electrode 16+weight per unit area of insulating film 18=weight per unit area of lower electrode 12+(weight per unit area of low acoustic impedance film 31a×α) (2)

In the second modification of the first embodiment, 0.1269+0.143=0.1269+(0.4224×α) is established from the equation (2), and α is about 0.34. Thus, when the insulating film 18 is provided on the upper electrode 16, the value of α is almost the same as the value of α in the above-mentioned equation (1) by using the equation (2). Therefore, in the second modification of the first embodiment, it is considered that the spurious 80 can be reduced by setting the value of α in the equation (2) to 0<α<0.96.

As described above, according to the first embodiment and the first modification thereof, the value of α obtained from the equation (1) is set within the range of 0<α<0.96. According to the second modification of the first embodiment, the value of α obtained from the equation (2) is set within the range of 0<α<0.96. That is, the weight (average thickness×density) per unit area of the low acoustic impedance film 31a closest to the lower electrode 12 in the resonance region 50 is represented by G1, and the weight (average thickness×density) per unit area of the lower electrode 12 in the resonance region 50 is represented by G2. The weight (average thickness×density) per unit area in the resonance region 50 of a film including the upper electrode 16 provided on the piezoelectric layer 14 in the resonance region 50 (the upper electrode 16 in the first embodiment and the first modification thereof, and the laminated film of the upper electrode 16 and the insulating film 18 in the second modification of the first embodiment) is represented by G3. In this case, 0<(G3−G2)/G1<0.96 is satisfied. Thus, the spurious 80 can be reduced.

In the first embodiment and its modification, the additional film 28 is not added to the film including the upper electrode 16 provided on the piezoelectric layer 14 in the resonance region 50 because the additional film 28 has a small influence on the second harmonic, but the additional film 28 may be added. Even in this case, since the additional film 28 is sufficiently small with respect to the size of the resonance region 50, the weight G3 per unit area in the resonance region 50 of the film including the upper electrode 16 provided on the piezoelectric layer 14 in the resonance region 50 hardly changes with or without the additional film 28.

As illustrated in FIG. 5B, when α is 0.1 or more and 0.75 or less, the magnitude of the spurious 80 is 3 dB or less. As illustrated in FIG. 3B, in the first embodiment, the magnitude of the spurious 81 caused by the second harmonic of the thickness longitudinal vibration is about 3 dB. Accordingly, when α is 0.1 or more and 0.75 or less, the magnitude of the spurious 80 caused by the second harmonic of the thickness-shear vibration can be made equal to or smaller than the magnitude of the spurious 81 caused by the second harmonic of the thickness longitudinal vibration. That is, by satisfying 0.1<(G3−G2)/G1<0.75, the magnitude of the spurious 80 caused by the second harmonic of the thickness-shear vibration can be made equal to or smaller than the magnitude of the spurious 81 caused by the second harmonic of the thickness longitudinal vibration.

As illustrated in FIG. 5B, when α is 0.15 or more and 0.7 or less, the magnitude of the spurious 80 is about 2 dB or less, and when α is 0.25 or more and 0.65 or less, the magnitude of the spurious 80 is about 1 dB or less. When α is 0.3 or more and 0.55 or less, the magnitude of the spurious 80 is about 0.5 dB or less. Therefore, from the viewpoint of reducing the spurious 80, it is preferable that 0.15<(G3−G2)/G1<0.7 is satisfied, it is more preferable that 0.25<(G3−G2)/G1<0.65 is satisfied, and it is even more preferable that 0.3<(G3−G2)/G1<0.55 is satisfied.

In the first embodiment and the first modification thereof, the upper electrode 16 is thicker than the lower electrode 12 in the resonance region 50 as illustrated in FIG. 1B and FIG. 6. Thus, satisfying 0<(G3−G2)/G1<0.96 can be easily realized.

In the first embodiment and the first and the second modifications thereof, the low acoustic impedance film 31 is the silicon oxide film. In this case, as illustrated in the simulation results of FIG. 3B, FIG. 7B, and FIG. 9B, the spurious 80 is reduced. By satisfying 0<(G3−G2)/G1<0.96, it is considered that the spurious 80 can be reduced even when the low acoustic impedance film 31 is the dielectric film other than the silicon oxide film.

In the first embodiment and the first modification thereof, the insulating film 18 is not provided on the upper electrode 16 as illustrated in FIG. 1B and FIG. 6, and only the upper electrode 16 is provided on the piezoelectric layer 14 from the central region 54 to the edge region 52 of the resonance region 50. In the second modification of the first embodiment, as illustrated in FIG. 8, the insulating film 18 is provided on the upper electrode 16, and the film provided on the piezoelectric layer 14 from the central region 54 to the edge region 52 of the resonance region 50 is the laminated film composed of the upper electrode 16 and the insulating film 18 provided on the upper electrode 16. In any case, by satisfying 0<(G3−G2)/G1<0.96, the spurious 80 can be reduced. [Simulation]

In a case where the lithium niobate layer is used for the piezoelectric layer 14 and α case where the aluminum nitride layer is used for the piezoelectric layer 14, a simulation for evaluating the spurious at a frequency higher than the antiresonance frequency was performed. The simulation was performed using the same model as in FIGS. 1A and 1B for a third comparative example using the lithium niobate layer as the piezoelectric layer 14 and α fourth comparative example using the aluminum nitride layer as the piezoelectric layer 14. The simulation conditions are as follows.

Conditions of Third Comparative Example
Wavelength λ, of acoustic wave: Twice thickness T14 of piezoelectric layer 14
Additional film 28: Silicon oxide film having thickness T28 of 65 nm
Upper electrode 16: Aluminum film having thickness T16 of 47 nm
Piezoelectric layer 14: Lithium niobate layer having thickness T14 of 470 nm (the X axis direction of the crystal orientation is the X direction, and the direction in which the +Z axis direction is rotated by 105° toward the +Y axis direction is the +Z direction)
Lower electrode 12: Aluminum film having thickness T12 of 47 nm
Low acoustic impedance film 31: Silicon oxide film having thickness T31 of 192 nm
High acoustic impedance film 32: Tungsten film having thickness T32 of 151 nm
Condition in X direction: Width of resonance region 50 in X direction is set to 30λ
Condition in Y direction: Width in Y direction is 0.5λ, and boundary condition is infinitely continuous

### Conditions of Fourth Comparative Example

Wavelength λ of acoustic wave: Twice thickness T14 of piezoelectric layer 14
Additional film 28: None
Upper electrode 16: Laminated film composed of ruthenium film and chromium film having thickness T16 of 168 nm (chromium film having thickness of 20 nm on ruthenium film having thickness of 148 nm)
Piezoelectric layer 14: Aluminum nitride layer having thickness T14 of 520 nm
Lower electrode 12: Laminated film composed of ruthenium film and chromium film having thickness T12 of 176 nm (ruthenium film having thickness of 121 nm on chromium film having thickness of 55 nm)
Low acoustic impedance film 31: Silicon oxide film having thickness T31 of 235 nm
High acoustic impedance film 32: Tungsten film having thickness T32 of 520 nm
Condition in X direction: Width of resonance region 50 in X direction is set to 70λ

Condition in Y direction: Width in Y direction is 0.5λ, and boundary condition is infinitely continuous

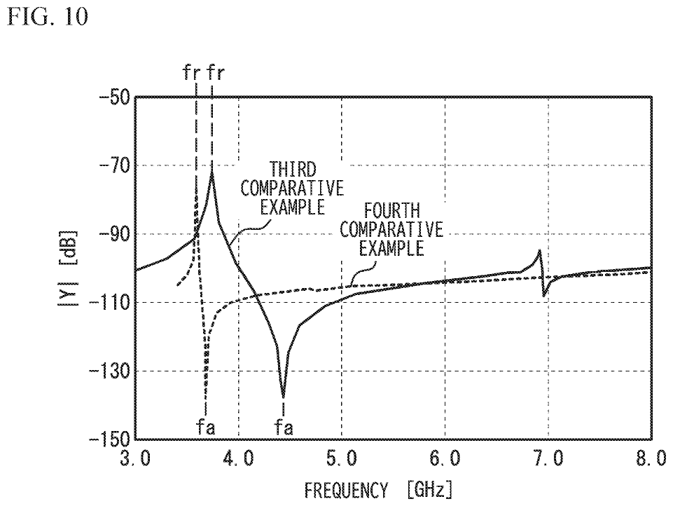

FIG. 10 is a diagram illustrating an absolute value Y of admittance to a frequency of the third comparative example and the fourth comparative example in the simulation. As illustrated in FIG. 10, in the third comparative example using the lithium niobate layer as the piezoelectric layer 14, compared to the fourth comparative example using the aluminum nitride layer as the piezoelectric layer 14, a large spurious occurs at a frequency higher than the antiresonance frequency fa. From this, it is understood that when the lithium niobate layer for exciting the acoustic wave in the thickness-shear vibration mode is used for the piezoelectric layer 14, the large spurious occurs as compared with when the aluminum nitride layer for exciting the acoustic wave in the thickness longitudinal vibration mode is used for the piezoelectric layer 14.

Therefore, when the single-crystal lithium niobate layer or the single-crystal lithium tantalate layer for exciting the acoustic wave in the thickness-shear vibration mode is used for the piezoelectric layer 14, the large spurious is likely to occur at the high frequency, and in this case, it is preferable that 0<(G3−G2)/G1<0.96 is satisfied as in the first embodiment and the first and the second modifications thereof.

By satisfying 0<(G3−G2)/G1<0.96, the balance between the upper electrode 16 side and the lower electrode 12 side of the second harmonic is improved, so that it is considered that the effect of reducing the spurious caused by the second harmonic can be obtained even when the aluminum nitride layer or the like which mainly excites the acoustic wave of the thickness longitudinal vibration mode is used for the piezoelectric layer 14.

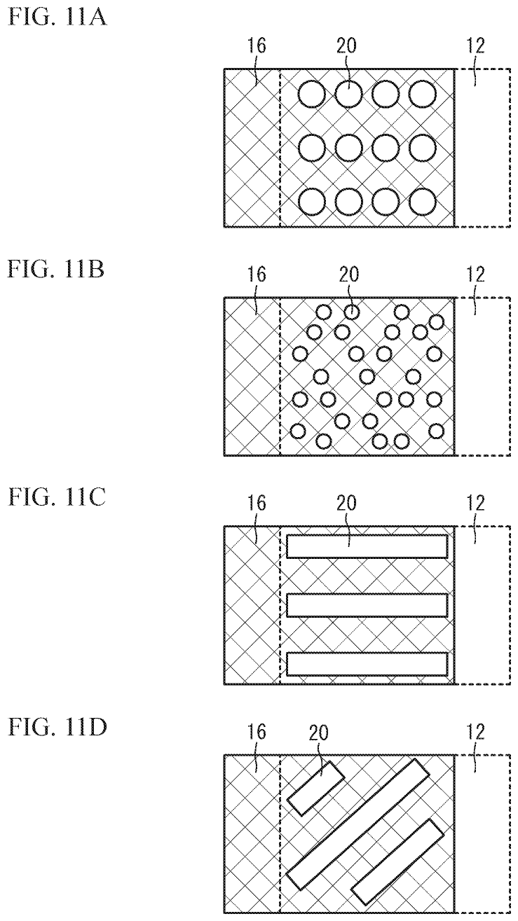

In the first embodiment and the first and second modifications thereof, the case where the upper electrode 16 is provided on the piezoelectric layer 14 to completely cover the resonance region 50 is described as an example, but the present disclosure is not limited to this case. FIGS. 11A to 11D are plan views illustrating another example of the upper electrode 16. In FIGS. 11A to 11D, hatching is given to the upper electrode 16 for clarity of the drawing. If 0<(G3−G2)/G1<0.96 is satisfied as illustrated in FIGS. 11A to 11D, openings 20 having circular or rectangular shapes may be provided in the upper electrode 16. The openings 20 may or may not penetrate the upper electrode 16. The openings 20 may be provided regularly or irregularly.

### Second Embodiment

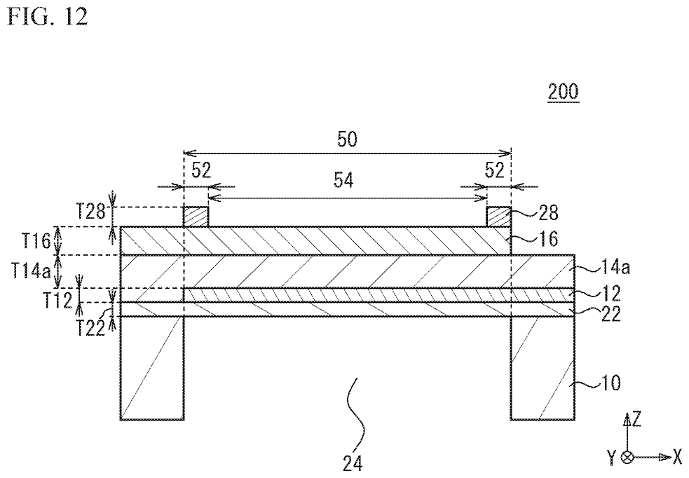

FIG. 12 is a cross-sectional view of an acoustic wave device 200 according to a second embodiment. As illustrated in FIG. 12, in the acoustic wave device 200, a cavity 24 is provided in the substrate 10 instead of the acoustic reflection film 30. The cavity 24 may penetrate the substrate 10 or may be provided as a recess on the upper surface of the substrate 10. An insulating film 22 is provided on the substrate 10 so as to cover the cavity 24, and α piezoelectric layer 14a is provided on the insulating film 22. The insulating film 22 is, for example, a silicon oxide film or a silicon nitride film. The lower electrode 12 is provided between the insulating film 22 and the piezoelectric layer 14a. The piezoelectric layer 14a is a single-crystal lithium niobate layer or a single-crystal lithium tantalate layer, and excites the acoustic wave of the thickness-shear vibration mode. Since other configurations are the same as those of the first embodiment, description thereof will be omitted.

The thickness of the additional film 28 is represented by T28. The thickness of the upper electrode 16 is represented by T16. The thickness of the piezoelectric layer 14a is represented by T14a. The thickness of the lower electrode 12 is represented by T12. The thickness of the insulating film 22 is represented by T22. The thickness T16 of the upper electrode 16 is larger than the thickness T12 of the lower electrode 12.

In the second embodiment, the lithium niobate layer or the lithium tantalate layer is used for the piezoelectric layer 14a. Therefore, as illustrated in FIG. 10, the large spurious is more likely to occur as compared with the case where the aluminum nitride layer is used for the piezoelectric layer 14a.

[Simulation]

The relationship between the thickness T16 of the upper electrode 16 and the magnitude of the spurious was obtained by simulation. The simulation conditions are as follows.
Wavelength λ of acoustic wave: Twice thickness T14a of piezoelectric layer 14a
Additional film 28: Silicon oxide film having thickness T28 of 70 nm
Upper electrode 16: Aluminum film having thickness T16 of between 44 nm and 100 nm
Piezoelectric layer 14a: Lithium niobate layer having thickness T14a of 470 nm (the X axis direction of the crystal orientation is the X direction, and the direction in which the +Z axis direction is rotated by 105° toward the +Y axis direction is the +Z direction)
Lower electrode 12: Aluminum film having thickness T12 of 44 nm
Insulating film 22: Silicon oxide (SiO₂) film having thickness T22 of 40 nm
Condition in X direction: Width of resonance region 50 in X direction is set to 8λ.
Condition in Y direction: Width in Y direction is 0.5λ, and boundary condition is infinitely continuous

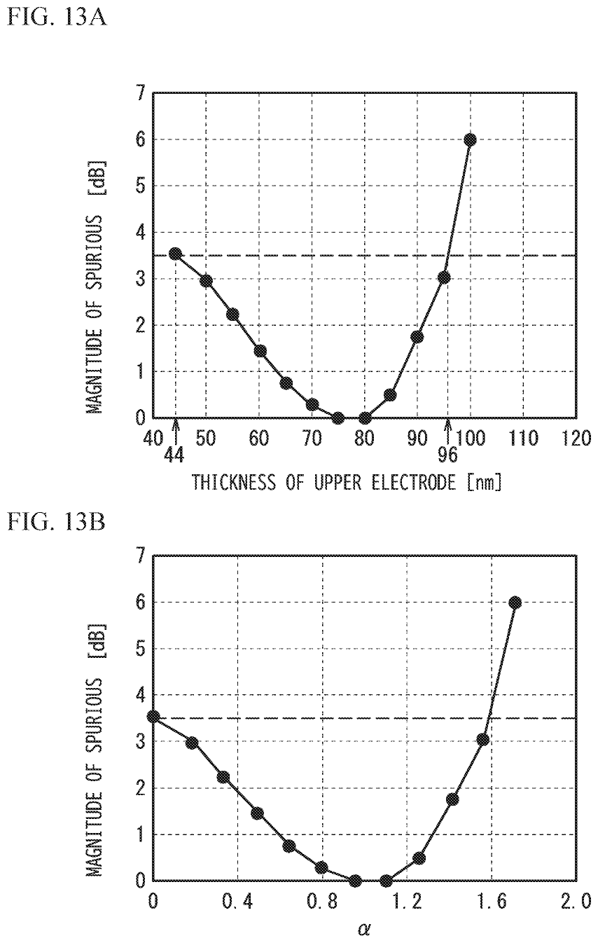

FIG. 13A is a diagram illustrating a simulation result of the magnitude of the spurious corresponding to the thickness T16 of the upper electrode 16. FIG. 13B is a diagram illustrating a case where the horizontal axis in FIG. 13A is converted into α in an equation (3).

In FIG. 13B, when α=0, the thickness T12 of the lower electrode 12 and the thickness T16 of the upper electrode 16 are both equal to 44 nm. The equation (3) is an assumed equation for the weight (average thickness×density) per unit area of each layer in the resonance region 50.

Weight per unit area of upper electrode 16=weight per unit area of lower electrode 12+(weight per unit area of insulating film 22×α)(3)

As illustrated in FIG. 13A, when the thickness T16 of the upper electrode 16 is larger than 44 nm and smaller than 96 nm, the spurious is reduced compared to when the thickness T16 of the upper electrode 16 is equal to the thickness T12 of the lower electrode 12, i.e., 44 nm. The spurious decreases as the thickness T16 of the upper electrode 16 increases until the thickness T16 of the upper electrode 16 is around 75 nm, but when the thickness T16 of the upper electrode 16 exceeds 80 nm, the spurious increases as the thickness T16 of the upper electrode 16 increases.

As illustrated in FIG. 13B, when the value of α in the equation (3) is larger than 0 and smaller than 1.6, the spurious is substantially reduced compared with the case where α is 0. The spurious decreases as α increases up to about 1.0, but when a exceeds 1.0, the spurious increases as α increases.

Therefore, in the second embodiment, the thickness T16 of the upper electrode 16 is adjusted so that the value of α obtained from the equation (3) becomes 0<α<0.96. Thus, the spurious can be reduced.

As described above, according to the second embodiment, the value of α obtained from the equation (3) is set within the range of 0<α<1.6. That is, the weight (average thickness×density) per unit area of the insulating film 22 in the resonance region 50 is represented by G1, and the weight (average thickness×density) per unit area of the lower electrode 12 in the resonance region 50 is represented by G2. The weight (average thickness×density) per unit area in the resonance region 50 of the film including the upper electrode 16 (the upper electrode 16 in the second embodiment) provided on the piezoelectric layer 14 in the resonance region 50 is represented by G3. In this case, 0<(G3−G2)/G1<1.6 is satisfied. Thus, the spurious can be reduced.

As illustrated in FIG. 13B, when α is 0.4 or more and 1.4 or less, the magnitude of the spurious is 2 dB or less. When α is 0.6 or more and 1.3 or less, the magnitude of the spurious is 1 dB or less. When α is 0.8 or more and 1.2 or less, the magnitude of the spurious is 0.5 dB or less. Therefore, from the viewpoint of reducing spurious, it is preferable to satisfy 0.4≤(G3−G2)/G1≤1.4, more preferably to satisfy 0.6≤(G3−G2)/G1≤1.3, and even more preferably to satisfy 0.8≤(G3−G2)/G1≤1.2.

In the second embodiment, as illustrated in FIG. 12, the upper electrode 16 is thicker than the lower electrode 12 in the resonance region 50. Thus, satisfying 0≤(G3−G2)/G1≤1.6 can be easily realized.

In the second embodiment, the insulating film 22 is a silicon oxide film. In this case, the spurious is reduced as illustrated in FIGS. 13A and 13B. If 0≤(G3−G2)/G1≤1.6 is satisfied, it is considered that spurious can be reduced even when the insulating film 22 is the dielectric film other than the silicon oxide film.

Although the insulating film 18 is not provided on the upper electrode 16 as illustrated in FIG. 12 in the second embodiment, the insulating film 18 may be provided on the upper electrode 16 as in the second modification of the first embodiment. In this case, the film including the upper electrode 16 provided on the piezoelectric layer 14 in the resonance region 50 is a laminated film composed of the upper electrode 16 and the insulating film 18. Also in the second embodiment, the openings 20 may be provided in the upper electrode 16 as illustrated in FIGS. 11A to 11D.

### Third Embodiment

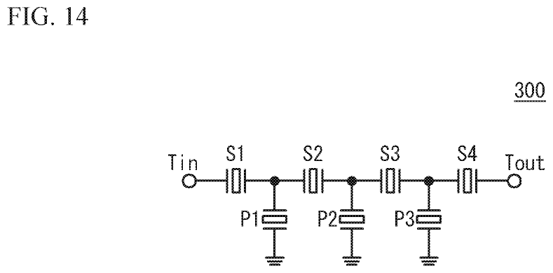

FIG. 14 is a circuit diagram of a filter 300 according to a third embodiment. As illustrated in FIG. 14, one or more series resonators S1 to S4 are connected in series between an input terminal Tin and an output terminal Tout. One or more parallel resonators P1 to P3 are connected in parallel between the input terminal Tin and the output terminal Tout. At least one of the series resonators S1 to S4 and the parallel resonators P1 to P3 can use the acoustic wave device of the first embodiment and the modifications thereof, and the second embodiment. The number of series resonators and parallel resonators can be set as needed. Although a ladder type filter is illustrated as an example of the filter, other filters such as a multi-mode type filter may be used.

### Fourth Embodiment

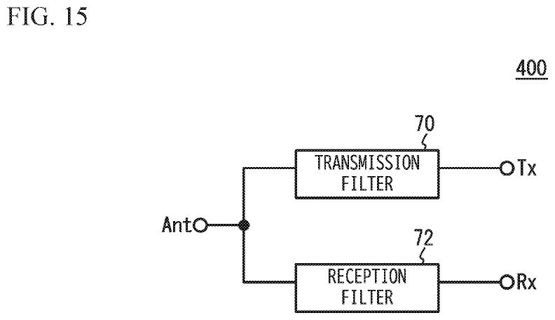

FIG. 15 is a circuit diagram of a duplexer 400 according to a fourth embodiment. As illustrated in FIG. 15, a transmission filter 70 is connected between a common terminal Ant and α transmission terminal Tx. A reception filter 72 is connected between the common terminal Ant and α reception terminal Rx. The transmission filter 70 allows a signal in the transmission band out of high frequency signals input from the transmission terminal Tx to pass through the common terminal Ant as a transmission signal, and suppresses signals having other frequencies. The reception filter 72 allows a signal in the reception band out of the high frequency signals input from the common terminal Ant to pass through the reception terminal Rx as a reception signal, and suppresses signals having other frequencies. At least one of the transmission filter 70 and the reception filter 72 may be the filter of the third embodiment. Although a duplexer is illustrated as an example of the multiplexer, a triple-plexer or a quad-plexer may be used.

Although the embodiments of the present disclosure have been described in detail, it is to be understood that the various change, substitutions, and alterations could be made hereto without departing from the spirit and scope of the invention.

What is claimed is:

1. An acoustic wave device comprising:
a substrate;
a lower electrode provided on the substrate;
a piezoelectric layer provided on the lower electrode;
an upper electrode provided on the piezoelectric layer so as to form a resonance region facing the lower electrode, the upper electrode and the lower electrode sandwiching the piezoelectric layer; and
a multilayered acoustic reflection film provided between the substrate and the lower electrode in the resonance region, the acoustic reflection film having one or more low acoustic impedance films and one or more high acoustic impedance films which are alternately laminated, and the acoustic reflection film satisfying 0<(G3−G2)/G1<0.96 where the G1 is a product of an average thickness in the resonance region of a first film and α density of the first film, the first film being a film closest to the lower electrode out of the one or more low acoustic impedance films and the one or more high acoustic impedance films, the G2 is a product of an average thickness of the lower electrode in the resonance region and α density of the lower electrode, and the G3 is a product of an average thickness in the resonance region of a second film including the upper electrode provided on the piezoelectric layer in the resonance region and α density of the second film.

2. An acoustic wave device comprising:
a substrate;
a lower electrode provided on the substrate;
a piezoelectric layer provided on the lower electrode;
an upper electrode provided on the piezoelectric layer so as to form a resonance region facing the lower electrode, the upper electrode and the lower electrode sandwiching the piezoelectric layer; and
a multilayered acoustic reflection film provided between the substrate and the lower electrode in the resonance region, the acoustic reflection film having one or more first films and one or more second films which are alternately laminated, the one or more first films including at least one of a silicon oxide film, a magnesium film, an aluminum film, and α titanium film, the one or more second films including at least one of a silicon nitride film, an aluminum nitride film, a copper film, an aluminum oxide film, a gold film, a molybdenum film, a tungsten film, and α tantalum oxide film, and the acoustic reflection film satisfying 0≤(G3−G2)/G1≤0.96 where the G1 is a product of an average thickness in the resonance region of a third film and α density of the third film, the third film being a film closest to the lower electrode out of the one or more first films and the one or more second films, the G2 is a product of an average thickness of the lower electrode in the resonance region and α density of the lower electrode, and the G3 is a product of an average thickness in the resonance region of a fourth film including the upper electrode provided on the piezoelectric layer in the resonance region and α density of the fourth film.

3. The acoustic wave device according to claim 1, wherein
0.1≤(G3−G2)/G1≤0.75 is satisfied.

4. The acoustic wave device according to claim 1, wherein
0.3≤(G3−G2)/G1≤0.55 is satisfied.

5. The acoustic wave device according to claim 1, wherein
the upper electrode is thicker than the lower electrode in the resonance region.

6. The acoustic wave device according to claim 1, wherein
the one or more low acoustic impedance films are silicon oxide films.

7. The acoustic wave device according to claim 6, wherein
the first film is a low acoustic impedance film.

8. The acoustic wave device according to claim 1, wherein
the second film includes the upper electrode and an insulating film provided on the upper electrode.

9. The acoustic wave device according to claim 1, wherein
the piezoelectric layer is a single-crystal lithium niobate layer or a single-crystal lithium tantalate layer.

10. An acoustic wave device comprising:
a substrate;
a lower electrode provided on the substrate;
a piezoelectric layer provided on the lower electrode and being a single-crystal lithium niobate layer or a single-crystal lithium tantalate layer;
an upper electrode provided on the piezoelectric layer so as to form a resonance region facing the lower electrode, the upper electrode and the lower electrode sandwiching the piezoelectric layer above a cavity provided below the lower electrode; and
an insulating film provided between the cavity and the lower electrode in the resonance region and satisfying 0<(G3−G2)/G1<1.6, where the G1 is a product of an average thickness of the insulating film in the resonance region and α density of the insulating film in the resonance region, the G2 is a product of an average thickness of the lower electrode in the resonance region and α density of the lower electrode, and the G3 is a product of an average thickness of a first film including the upper electrode provided on the piezoelectric layer in the resonance region and α density of the first film.

11. A filter comprising:
the acoustic wave device according to claim 1.

12. A multiplexer comprising:
the filter according to claim 11.

13. The acoustic wave device according to claim 2, wherein
0.1≤(G3−G2)/G1≤0.75 is satisfied.

14. The acoustic wave device according to claim 2, wherein
0.3≤(G3−G2)/G1≤0.55 is satisfied.

15. The acoustic wave device according to claim 2, wherein
the upper electrode is thicker than the lower electrode in the resonance region.

16. The acoustic wave device according to claim 2, wherein
the fourth film includes the upper electrode and an insulating film provided on the upper electrode.

17. The acoustic wave device according to claim 2, wherein
the piezoelectric layer is a single-crystal lithium niobate layer or a single-crystal lithium tantalate layer.
